(19) United States
(12) Patent Application Publication
(10) Pub. No.: US 2012/0092021 A1
(43) Pub. Date: Apr. 19, 2012

(54) Test Structure for GIP panel

(75) Inventors: Ming-Chuan LEE, Zhongli City (TW); Shih-Hao HUANG, Bade City (TW); Chi-Wen WU, Taoyuan City (TW)

(73) Assignee: CHUNGHWA PICTURE TUBES, LTD., Bade City (TW)

(21) Appl. No.: 13/016,943

(22) Filed: Jan. 28, 2011

(30) Foreign Application Priority Data
Oct. 19, 2010 (TW) 099220190

(51) Int. Cl. G01R 31/02

(52) U.S. Cl. 324/537

(57) ABSTRACT

The present invention discloses the test structure for a display panel, particularly for the GIP panel driven by the gate drivers on both left and right side of the panel. Through a plurality of dedicated pads designed on the GIP panel and a control circuit in probe card, the disclosed test structure can reduce the requirement of test equipments and thus save test cost.

### CROSS-REFERENCE TO RELATED APPLICATION

This present application claims priority to TAIWAN Patent Application Serial Number 099220190, filed Oct. 19, 2010, which is herein incorporated by reference.

### TECHNICAL FIELD

This invention relates to a test structure for a GIP (gate in panel) panel, and particularly to a test structure for a panel having gate driving circuits on left and right side of the panel. The disclosed test structure of the present invention can reduce the testing cost in mass production.

### BACKGROUND OF THE RELATED ART

In order to reduce the manufacture cost of a display panel, more and more panel makers directly fabricate gate drivers on the panel rather than purchase gate driver ICs and then mount them on the panel. The panel with pre-made gate driving circuits is called GIP (gate in panel) panel or gateless panel. In general, the panel with larger size or higher resolution will has gate driving circuits on left and right side of the panel to drive the odd and the even gate lines, respectively or to drive the gate lines on the left half portion and on the right half portion, respectively.

Traditionally, as shown in FIG. 1, the test procedure of the GIP panel 100 is to turn on the gate drivers on the left side to test the pixels controlled by the odd gate lines 101, and then to turn on the gate drivers on the right side to test the pixels controlled by the even gate lines 102. Finally, the test results of the pixels driven by the odd and the even gate lines are combined to analyze the defect distribution of the panel.

The traditional test method requires two sets of test signal generator to test the panel while the both side of gate drivers are turned on concurrently. Generally speaking, one test equipment is equipped with one set of test signal generator so it will need two test equipments for testing every panel during mass production. Given that due to the limited resources, only one test equipment is allowed for testing every panel in mass production. It will need two steps to accomplish panel test. The operators need to setup the test environment to test the half pixels, driven by the odd or the even gate lines, of the panel, and then unload and re-setup the test equipment to test the other half pixels. The above-mentioned traditional test methods require either more test equipments or longer testing time and certainly they will increase test cost.

Therefore, the present invention discloses a novel test structure to test GIP panels, which can reduce the requirement of test equipments so as to lower the production cost.

### SUMMARY

The present invention disclosed a test structure for GIP panels to effectively reduce the production cost because of saving some of the test equipments. The test structure of present invention comprises a panel having an upper substrate and a lower substrate. The upper substrate or the lower substrate can be as a first substrate which comprises a first gate driving circuit, a second gate driving circuit, a plurality of gate lines, a plurality of source lines, and a plurality of connection pads formed thereon. The first and the second gate driving circuits can be configured to be a shift register so as to turn on (or activate) the gate lines sequentially. The connection pads, which can transmit the signals comprising clock, inverse clock, start, and reference voltage, are designed to electrically connect to the first gate driving circuit or the second driving circuit.

In the preferred embodiment, the gate lines on the panel are separated to two groups, the odd and the even. The odd gate lines are driven by the first gate driving circuit and the even gate lines are driven by the second gate driving circuit or, on the contrary, the odd gate lines are driven by the second gate driving circuit and the even gate lines are driven by the first gate driving circuit.

In one embodiment, the gate lines on the panel are separated to two groups, the left half porting and the right half portion. The left half gate lines are controlled by the first gate driving circuit and the right half gate lines are controlled by the second gate driving circuit.

In the preferred embodiment, the connection pads are pre-designed to be electrically connected to the first driving gate circuit. When testing the panel, the connection pads will be electrically connected to the second gate driving circuit via a test system so that test signals can be sent from the first gate driving circuit to the second gate driving circuit.

In one embodiment, the connection pads are pre-designed to be electrically connected to the second driving gate circuit. When testing the panel, the connection pads will be electrically connected to the first gate driving circuit via the test system so that test signals can be sent from the second gate driving circuit to the first gate driving circuit.

The test system comprises a probe station, a probe card, a signal generator, and an instrument. A plurality of probes and a control circuit are implemented on the probe card and the probe station can manipulate the probe card to connect the probes to the first gate driving circuit, the second gate driving circuit, and the connection pads, respectively. The control circuit on the probe card acts as a switch to connect or disconnect an electrical path and can be controlled by the signal generator during the test. The purpose of the control circuit is to provide an electrical path between the connection pads and the first or the second gate driving circuit. The signal generator generates a plurality of pulse signals and the test signals comprising a clock signal, an inverse clock signal, a start signal and a reference voltage signal. The instrument has a plurality of channels to receive and measure voltage signals from the source lines.

A test procedure based on the test structure of present invention will be described as follows:

In the preferred embodiment, providing the first substrate and the above-mentioned test system, the probe station manipulates the probe card to connect the probes to the first gate driving circuit, the second gate driving circuit and the connection pads. The first and the second gate driving circuits are configured to be a shift register and the control circuit on the probe card is set to be turned on, so that the test signals, generated by the signal generator, can be sequentially transmitted from the first gate driving circuit, via the connection pads and the probe card, to the second gate driving circuit. The gate lines will be turned on, sequentially and clock-cycle based. In other words, only one gate line is activated in one clock cycle and then the next is activated in next clock cycle in turn until all the gate lines are scanned.

While one gate line is activated, the signal generator sends the pulse signals to all source lines to write a fixed voltage into the pixels on the activated gate line, and accordingly all pixels will be written by a fixed voltage once all the gate lines were activated. By activating the gate lines in turn again, the voltages of all pixels can be read out from the source lines and measured by the instrument so that the defect distribution of the panel can be analyzed, therefore.

### BRIEF DESCRIPTION OF THE DRAWINGS

The above objects, and other features and advantages of the present invention will become more apparent after reading the following detailed description when taken in conjunction with the drawings, in which:

FIG. 1 illustrates a prior art of GIP panel test.

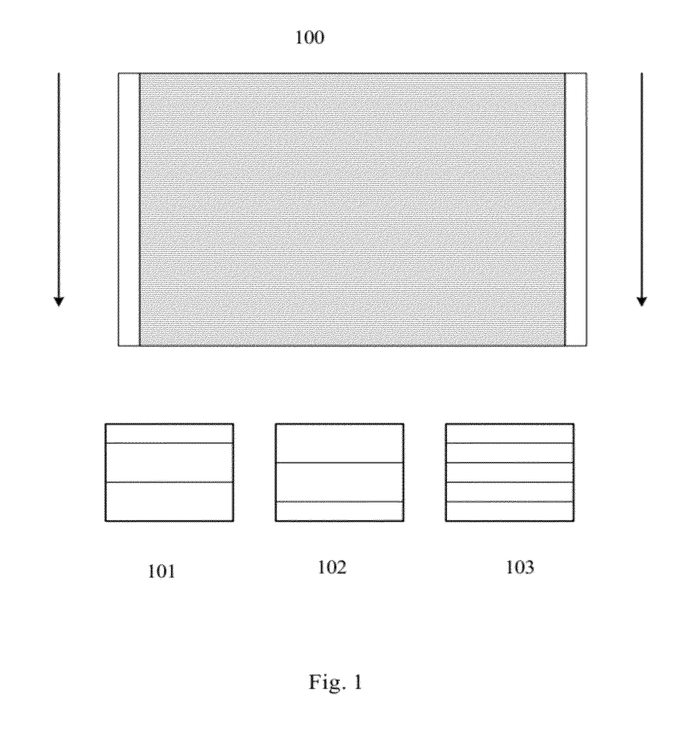

FIG. 2 shows a substrate comprising the gate driving circuits on the left and the right side, a plurality of gate lines, and a plurality of source lines.

FIG. 3 illustrates the structure and the functional behavior of a shift register.

FIG. 4 shows the test structure of present invention.

### DETAILED DESCRIPTION

The present invention will be described in detail by using the following embodiments and it will be recognized that those descriptions and examples of embodiments are used to illustrate but not to limit the claims of the present invention. Hence, other than the embodiments described in the following, the present invention may be applied to the other substantially equivalent embodiments.

For reducing the requirement of test equipments during mass production, the present invention discloses a test structure for GIP panels and is particularly applied to the GIP panel with pre-made gate driving circuits on left and right side of the panels.

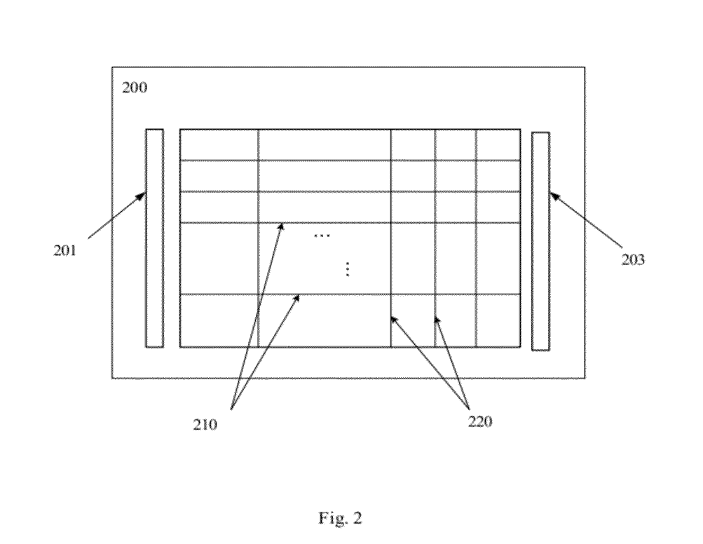

In general, a display panel comprises two substrates, the upper and the lower, which are made of transparent materials, such as glass. As shown in FIG. 2, one substrate 200 has pre-made gate driving circuits on both side, and hereinafter we name the gate driving circuit on the left the first gate driving circuit 201, and the gate driving circuit on the right the second gate driving circuit 203, respectively. Besides, there are a plurality of horizontal gate lines 210 and a plurality of vertical source lines 220 on the substrate 200. One pixel is formed thereon in the intersection area of a gate line 210 and a source line and controlled by the gate line 210 and the source line 220 as well. The gate driving circuits 201 203 can turn on, or activate, the gate lines 210. During the period of one gate line 210 being activated, the vertical source lines 220, which intersect the activated gate line 210, can write voltage signals into pixels to control voltages of pixels. Similarly, using the foregoing gate controlling method, voltages of pixels can be read out by source lines 220.

In one embodiment, all gate lines 210 are separated to two groups, the odd and the even, and the first gate driving circuit 201 controls the odd of gate lines 210 and the second gate driving circuit 203 controls the even of gate lines 210.

In one embodiment, all gate lines 210 are separated to two groups, the odd and the even, and the first gate driving circuit 201 controls the even of gate lines 210 and the second gate driving circuit 203 controls the odd of gate lines 210.

In one embodiment (not shown in the FIGURES), the gate lines 210 are separated to two groups, the left half portion and the right half portion, and the first gate driving circuit 201 controls the left half gate lines, and the second gate driving circuit 203 controls the right half gate lines.

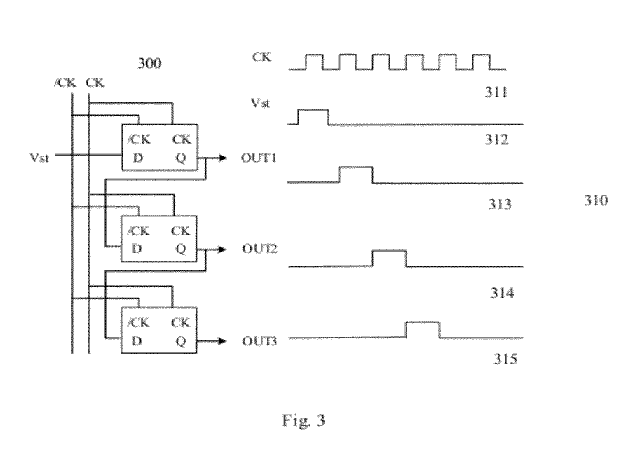

As shown in FIG. 3, the gate driving circuits 201 203 will be configured to be a shift register 300. Since the functions of a shift register are well-known for those skilled in the art, the description of the operation behaviors in detail herein is omitted. Once the gate driving circuits 201 203 were configured to be the shift register 300, with applying a clock signal (CK) 311 and a start signal (Vst) 312 to the shift register 300, the shift register 300 will sequentially outputs the pulse signals OUT1 313, OUT2 314, and OUT3 315 by every clock cycle to successively activate the gate lines 210. Owing to the disconnection between the gate driving circuits 201 203, the start signal (Vst) 312 is required to respectively apply to the first gate driving circuit 201 and the second driving circuit 203 for turning on the all gate lines 210 on the substrate 200.

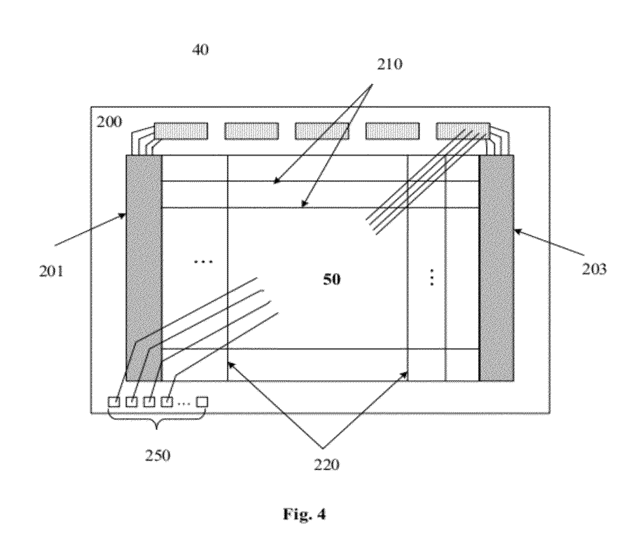

In the preferred embodiment, as shown in FIG. 4, a plurality of connection pads 250 are fabricated on the substrate 200 and electrically connected to the first gate driving circuits 201, so that the signals transmitted from the first gate driving circuits 201 can be received by the connection pads 250.

In one embodiment (not shown in the FIGURES, a plurality of connection pads 250 are fabricated on the substrate 200 and electrically connected to the second gate driving circuit 203, so that the signals transmitted from the second gate driving circuit 203 can be received by the connection pads 250.

A test system is provided and it includes a signal generator 40, a probe card 50, a probe station, and an instrument (not shown in the FIG. 4).

The signal generator 40 can generate a plurality of pulse signals and the test signals include a clock signal (CK), an inverse clock signal (/CK), a start signal (Vst), a reference voltage (Vg). The test system manipulates the probe card 50, which has a plurality of probes thereon, to connect the probes to the gate driving circuits 201 203, the connection pads 250 and the other pads required during the test, respectively. The probe card 50 further includes a control circuit acting as a switch to control the connection or disconnection between the connection pads 250 and the first gate driving circuit 201 or the second gate driving circuits 203.

In one embodiment, if the connection pads 250 are pre-designed to be electrically connected to the first gate driving circuit 201, the control circuit on the probe card 50 is able to connect the connection pads 250 to the second gate driving circuit 203 during the test.

In one embodiment, if the connection pads 250 are pre-designed to be electrically connected to the second gate driving circuit 203, the control circuit on the probe card 50 is able to connect the connection pads 250 to the first gate driving circuit 201 during the test.

In the preferred embodiment, before executing the panel test, the gate driving circuits 201 203 are configured to be a shift register. The signal generator 40 sends the test signals, via the probe station and the probe card 50, to the first gate driving circuit 201 and then the first gate driving circuit 201 sequentially turns on one odd gate line by every clock cycle. After the last odd gate line was activated, the test signal will be transmitted, through the connection pads 250 and the control circuit, to the second gate driving circuit 203. As the same behavior of the first gate driving circuit 201, the second gate driving circuit 203 will also sequentially, by every clock cycle, turn on one even gate line until the last even gate line.

In one embodiment, before executing the panel test, the gate driving circuits 201 203 are configured to be a shift register. The signal generator 40 sends the test signals, via the probe station and the probe card 50, to the first gate driving circuit 201 and then the first gate driving circuit 201 sequentially turns on one even gate line by every clock cycle. After the last even gate line was activated, the test signal will be transmitted, through the connection pads 250 and the control circuit, to the second gate driving circuit 203. As the same behavior of the first gate driving circuit 201, the second gate driving circuit 203 will also sequentially, by every clock cycle, turn on one odd gate line until the last odd gate line.

By using the aforementioned test structure and test procedure, only one set of signal generator 40 is required to test the panel with gate driving circuits on the left and the right side.

The more detail test procedure will be described as follows: While the gate driving circuits 201 203 turn on one gate line, the signal generator 40 or the other instruments can send pulse signals to all source lines 220, and consequently all the pixels on the activated gate line were set to a fixed voltage. For the reason that every gate line 210 will be activated sequentially, all of the pixels on the panel will be written with a fixed voltage. Finally, by activating the gate lines in turn again, the voltages of all pixels can be read out from the source lines 220 and measured by the instrument so that the defect distribution of the panel can be analyzed.

Just like the behavior of a shift register 300, as shown in FIG. 3, the way to sequentially activate the gate line is that for every one clock cycle only one gate line will be tuned on by a pulse signal and the pulse signal will shift to the next gate line in turn by every one clock cycle.

Although preferred embodiments of the present invention have been described, it will be understood by those skilled in the art that the present invention should not be limited to the described preferred embodiments. Rather, various changes and modifications can be made within the spirit and scope of the present invention, as defined by the following Claims.

What is claimed is:

1. A test structure for GIP panel comprising:
a panel having a first substrate and thereon a first gate driving circuit, a second gate driving circuit, a plurality of gate lines, and a plurality of source lines are formed on said first substrate;
a plurality of connection pads formed on said first substrate thereon, wherein said connection pads are electrically connected to said first gate driving circuit; and
while said panel is under testing, said connection pads, via a test system, are electrically connected to said second gate driving circuit so as to allow test signals be sequentially sent from said first gate driving circuit to said second gate driving circuit by way of said connection pads and said test system.

2. A test structure for GIP panel according to claim 1, wherein said panel comprises an upper substrate and a lower substrate, and said first substrate acting as said upper substrate or said lower substrate.

3. A test structure for GIP panel according to claim 1, wherein odd of said gate lines are driven by said first gate driving circuit and even of said gate lines are driven by said second gate driving circuit.

4. A test structure for GIP panel according to claim 1, wherein odd of said gate lines are driven by said second gate driving circuit and even of said gate lines are driven by said first gate driving circuit.

5. A test structure for GIP panel according to claim 1, wherein said gate lines are separated to a left half group and a right half group.

6. A test structure for GIP panel according to claim 5, wherein said left half group is controlled by said first gate driving circuit and said right half group is controlled by said second gate driving circuit.

7. A test structure for GIP panel according to claim 1, wherein said first gate driving circuit and said second gate driving circuit are set up to act as a shift register so as to turn on said gate lines sequentially.

8. A test structure for GIP panel according to claim 1, wherein said connections pads transmit signals comprising clock, inverse clock, start, and reference voltage, respectively.

9. A test structure for GIP panel according to claim 1, further comprising:
a probe card having a control circuit and a plurality of probes thereon; wherein
said probe card is electrically connect to said first gate driving circuit, said second gate driving circuit, and said connection pads; and
a signal generator coupled to said probe card for generating test signals and a plurality of pulse signals.

10. A test structure for GIP panel according to claim 9, wherein said probes, during testing said panel, are electrically connected to said first gate driving circuit, said second gate driving circuit, and said connection pads respectively;

11. A test structure for GIP panel according to claim 9, wherein said control circuit controls the connection or disconnection between said connection pads and said second gate driving circuit.

12. A test structure for GIP panel according to claim 9, wherein said test signals comprises a clock signal, an inverse clock signal, a start signal, a reference voltage signal and a plurality of pulse signals.

13. A test structure for GIP panel according to claim 9, wherein said connection pads, via said control circuit, are electrically connected to said second gate driving circuit so that said test signals are sent from said first gate driving circuit to said second gate driving circuit by way of said connection pads, said probes and said control circuit.

14. A test structure for GIP panel according to claim 9, wherein said pulse signals are sent to said source lines in order to write a fixed voltage into pixels on said gate line during one of said gate lines turned on.

15. A test structure for GIP panel according to claim 9, wherein voltages on said source lines are read out to analyze the defect distribution of said panel during one of said gate lines turned on.

16. A test structure for GIP panel according to claim 9, wherein said control circuit acts as a switch to connect or disconnect an electrical path.

17. A test structure for GIP panel according to claim 9, wherein said control circuit is controlled by said signal generator.

18. A test structure for GIP panel comprising:
a panel having a first substrate and thereon a first gate driving circuit, a second gate driving circuit, a plurality of gate lines, and a plurality of source lines are formed on said first substrate;
a plurality of connection pads formed on said first substrate thereon, wherein said connection pads are electrically connected to said second gate driving circuit;
and while said panel is under testing, said connection pads, via a test system, are electrically connected to said first gate driving circuit so as to allow test signals be sequentially sent from said second gate driving circuit to said first gate driving circuit by way of said connection pads and said test system.
